(19) United States
(12) Patent Application Publication
(10) Pub. No.: US 2011/0033718 A1
(43) Pub. Date: Feb. 10, 2011

(54) ZnO THIN FILM

(75) Inventors: Ken Nakahara, Kyoto (JP); Hiroyuki Yuji, Kyoto (JP); Kentaro Tamura, Kyoto (JP); Shunsuke Akasaka, Kyoto (JP); Masashi Kawasaki, Miyagi (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(73) Assignee: ROHM CO., LTD., Kyoto-shi, Kyoto (JP)

(21) Appl. No.: 12/450,597

(22) PCT Filed: Apr. 2, 2008
(86) PCT No.: PCT/JP2008/056566

§ 371 Date: Mar. 18, 2010

(30) Foreign Application Priority Data
Apr. 4, 2007 (JP) 2007-098813
Jan. 8, 2008 (JP) 2008-001474

(51) Int. Cl. C30B 29/16; B32B 9/00

(52) U.S. Cl. 428/457; 428/697; 428/702; 428/701

(57) ABSTRACT

Provided is a ZnO-based thin film which is doped with p-type impurities and which can be used for various devices. An MgₓZn₁₋ₓO film (0≦x≦0.5) is formed on top of a substrate so as to have an acceptor concentration of a p-type dopant that is 5×10²⁰ cm⁻³ or less. An acceptor concentration exceeding 5×10²⁰ cm⁻³ results in the formation of a mixed crystal of the p-type impurities and the ZnO crystal as the base material. Accordingly, no high-quality ZnO-based thin film doped to be p-type can be obtained. This fact is testified by the change observed in the ZnO secondary ion intensity.

### TECHNICAL FIELD

The present invention relates to a ZnO-based thin film made of an MgZnO film doped with p-type impurities.

### BACKGROUND ART

Nitrides and oxides are examples of compounds containing an element whose simple substance is in the gas state. Nitrides have created a huge market and a wide variety of research themes, due to the industrial success of blue LEDs. On the other hand, oxides have a wide variety of physical properties that any of conventional semiconductors, metals, and organic substances cannot achieve, and thereby are one of the hottest research fields. Some examples of the oxides are: superconductive oxides typified by YBCO; transparent conducting materials typified by ITO, and giant magnetoresistive materials typified by (LaSr)MnO₃.

For semiconductors, doping is generally performed to intentionally add a controlled amount of impurities to a base material. Doping draws out various functions of semiconductors. Doping is also performed for oxides. If metals are selected as dopants for oxides, composite oxides are more likely to be made, as understandable from the fact that an oxide can contain as many different elements as possible. In addition, a metal has plural valences with respect to oxygen in many cases. This is undesirable for the control of doping. In order to deal with this situation, doping to replace oxygen is conceivable. However, if elements other than metal elements are selected as dopants, most of the eligible ones are gas elements. Accordingly, a gas element is most likely to be selected as the dopant.

Let ZnO, which is a kind of oxides, be taken as an example. ZnO attracts much attention for its multi-functionality, its high light-emitting potential, and other properties. Despite such excellent properties, it has taken a long time for ZnO to become a prosperous semiconductor-device material. This is because ZnO has one of the most serious drawbacks in which a p-type ZnO was not able to be obtained due to a difficulty in acceptor doping.

However, in recent years, as described in Non-Patent Documents 1 and 2, the progress in technologies has made p-type ZnO available and also light emission using p-type ZnO has been confirmed. Consequently, more and more researches on p-type ZnO have been conducted. In addition, the conditions for forming a p-type ZnO-based thin film are described in Patent Document 1.

Patent Document 1: U.S. Pat. No. 6,410,162-B

### Non-Patent Document 1: A. Tsukazaki et al., JJAP 44 (2005) L643

### Non-Patent Document 1: A. Tsukazaki et al., Nature Material 4 (2005) 42

### DISCLOSURE OF THE INVENTION

### Problems to be Solved by the Invention

Patent Document 1 describes: the minimum value of the acceptor concentration, the resistivity, and the range of carrier mobility. Patent Document 1, however, has no description of the maximum value of the acceptor concentration or the like. In this regard, depending on a doping amount of p-type impurities, the crystallinity of the base material of the ZnO-based thin film doped with the p-type impurities may be changed, or the doped impurities may fail to show p-type properties. Moreover, since any element can form an oxide, an unintentional composite oxide may be formed as a hetero-phase. In addition, in a case of a ZnO-based thin film containing Mg, the proportion of Mg composition may change properties such as the activation rate of the dopant. No guide lines have been established to address these problems. Accordingly, the conditions described in Patent Document 1 are not sufficient at all if a device is to be fabricated using a ZnO-based thin film.

The present invention has been made to solve the above-described problems, and has an object to provide a ZnO-based thin film which is doped with p-type impurities and which can be used in a variety of devices.

### Means for Solving the Problems

In order to achieve the above object, the invention according to claim 1 is a ZnO-based thin film characterized by comprising a MgₓZn₁₋ₓO film (0≦x≦0.5) being formed on top of a substrate, containing at least one kind of p-type dopant, and having an acceptor concentration that is 5×10²⁰ cm⁻³ or less.

In addition, the invention according to claim 2 is the ZnO-based thin film according to claim 1 characterized in that the MgₓZn₁₋ₓO film has a Mg-composition X that is lower than 0.39.

Additionally, the invention according to claim 3 is the ZnO-based thin film according to claim 1 characterized in that the ZnO-based thin film according to claim 1 characterized in that the MgₓZn₁₋ₓO film has a Mg-composition X that is lower than 0.26.

Moreover, the invention according to claim 4 is the ZnO-based thin film according to any of claims 1 to 3 characterized in that the p-type dopant is an element selected from group VB elements.

Further, the invention according to claim 5 is the ZnO-based thin film according to claim 4 characterized in that the selected element is nitrogen.

Furthermore, the invention according to claim 6 is the ZnO-based thin film according to any of claims 1 to 5 characterized in that the substrate is made of a ZnO-based material.

In addition, the invention according to claim 7 is the ZnO-based thin film according to any of claims 1 to 6 characterized in that a normal line to a principal surface of the substrate inclines from c-axis of the crystal axes of the MgₓZn₁₋ₓO film.

Additionally, the invention according to claim 8 is the ZnO-based thin film according to any of claims 1 to 7 characterized in that the normal line to the principal surface of the substrate inclines from c-axis of the crystal axes of the substrate.

Moreover, the invention according to claim 9 is the ZnO-based thin film according to any of claims 7 and 8 characterized in that the direction in which the normal line to the principal surface of the substrate inclines is the m-axis direction.

### EFFECTS OF THE INVENTION

A ZnO-based thin film of the present invention is made of an MgₓZn₁₋ₓO film (0≦x≦0.5) and the p-type impurity concentration is 5×10²⁰ cm⁻³ or less. Accordingly, it is possible to prevent the formation of a mixed crystal of the p-type impurities and the ZnO crystal as the base material, and thus to fabricate a high-quality ZnO-based thin film doped to be p-type.

### BRIEF DESCRIPTION OF THE DRAWINGS

FIG. 1 is a chart illustrating the relationship between the nitrogen concentration and the ZnO secondary ion intensity in a ZnO thin film.

FIG. 2 is a chart illustrating a comparison between the nitrogen concentration of ZnO and the nitrogen concentration of MgZnO.

FIG. 3 is diagram illustrating a semiconductor element including an MgZnO layer as the uppermost layer.

FIG. 4 is a table showing various patterns that differ from one another in the film thickness of the uppermost layer shown in FIG. 3, the proportion of the Mg composition, and the nitrogen concentration.

FIG. 5 shows charts each of which illustrates a curve obtained by measuring the current-voltage characteristic of the corresponding one of the patterns shown in FIG. 4.

FIG. 6 is a chart illustrating some electric characteristics of phosphorous-doped ZnO.

FIG. 7 shows diagrams illustrating the chemical stability of M-plane.

FIG. 8 shows diagrams illustrating the chemical stability of M-plane.

FIG. 9 shows diagrams illustrating the thermal stability of M-plane.

FIG. 10 shows diagrams illustrating the surface states of MgₓZn₁₋ₓO substrates that differ from one another in the off-angle, in the a-axis direction, of the normal line to the principal surface of the substrate.

FIG. 11 shows diagrams each of which illustrates the surface of a film formed on an MgₓZn₁₋ₓO substrate of a case where the normal line to the principal surface of the substrate has an off-angle in the m-axis direction.

FIG. 12 is a diagram illustrating the relationships between the normal line to the principal surface of the substrate and each of the crystal axes of the substrate (i.e., c-axis, m-axis, and a-axis).

FIG. 13 shows diagrams each of which illustrates the relationships between the inclination of the normal line to the principal surface of the substrate, step edges and m-axis.

FIG. 14 shows diagrams each of which illustrates the surface of a substrate of a case where the normal line to the principal surface of the substrate has an off-angle only in the m-axis direction.

FIG. 15 shows diagrams each of which illustrates the surface of a substrate of a case where the normal line to the principal surface of the substrate has an off-angle in the m-axis direction and an off-angle in the a-axis direction.

FIG. 16 shows diagrams illustrating the surface states of MgₓZn₁₋ₓO layers obtained by crystal growth performed with Mg-component proportions X that are different from one another.

### DESCRIPTION OF SYMBOLS

1 ZnO substrate
2 ZnO layer
3 Mg_{0.1}ZnO layer
4 MQW layer
5 MgₓZn₁₋ₓO layer

### BEST MODES FOR CARRYING OUT THE INVENTION

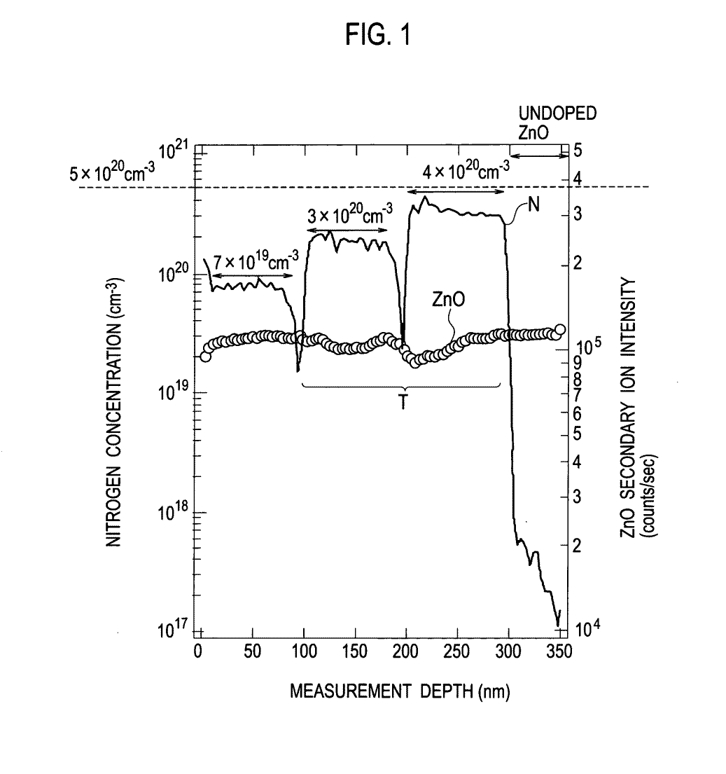

An embodiment of the invention will be described below by referring to the drawings. FIG. 1 illustrates the relationship between the property change of a ZnO thin film and the amount of doped nitrogen. Firstly, in order to form a ZnO thin film with favorable crystal properties, it is necessary to grow the ZnO crystal at a high growth temperature. If a ZnO crystal grows at a growth temperature that is high enough to keep the favorable crystal properties, nitrogen can hardly be doped into the ZnO thin film. This is because the chemical activity of oxygen is so high that it is difficult for zinc to combine with nitrogen. In addition, as has been already known, if the nitrogen is doped into a ZnO thin film, a Zn-rich condition is necessary (see K. Nakahara et al., Journal of Crystal Growth, Vol. 237-239 (2002), pp. 503-508). At a growth temperature that is set so high, it is difficult to accomplish an effective Zn-rich condition by controlling (i.e., raising or lowering) the ratio of Zn to be supplied. Rather, decreasing of oxygen to be supplied is a simpler and more effective means for accomplishing an effective Zn-rich condition.

So the inventors increased the amount of doped nitrogen by decreasing the amount of oxygen supply in accordance with the method invented by the same inventors (JP-2007-79805-A). Specifically, for example, if an oxygen radical cell is used for the purpose of supplying oxygen, the amount of doped nitrogen concentration can be increased either by decreasing the amount of oxygen gas to be introduced into the oxygen radical cell or by decreasing the radio-frequency output.

The inventors measured, by the secondary ion mass spectroscopy (SIMS), the nitrogen concentration of a nitrogen-doped ZnO thin film that is grown on an undoped ZnO substrate by varying the nitrogen (N) concentration. FIG. 1 shows the measurement results. The changing of the nitrogen-concentration curve denoted by N in FIG. 1 has three steps: a first concentration step around 7×10¹⁹ cm⁻³; a second concentration step around 3×10²⁰ cm⁻³; and a third concentration step around 4×10²⁰ cm⁻³. The ZnO secondary ion intensity corresponding to each nitrogen concentration changes within a range denoted by Tin FIG. 1, that is, within a range corresponding to the nitrogen concentration ranging from the latter part of 10¹⁹ cm⁻³ to the middle part of 10²⁰ cm⁻³. The ZnO secondary ion intensity changes as the nitrogen concentration starts to enter 10²⁰ cm⁻³.

The secondary ion concentration in the SIMS is determined by the base material. To put it differently, if the material of the base material is changed, the secondary ion intensity is also changed (matrix effect). Changes in the ZnO secondary ion concentration mean that changes of matrix. In other words, the base material ZnO is changed, by the formation of a mixed crystal, into a different base material ZnO such as ZnON. Such change is beyond the concept of doping relevant to the field of semiconductor. The product obtained by such change differs from the target thin film for semiconductor devices, and is therefore unusable. An example of the change in the secondary ion intensity caused by the matrix change of Ga is described in Ken Nakahara et al., Applied Physics Letters, Vol. 79 (2001) 4139.

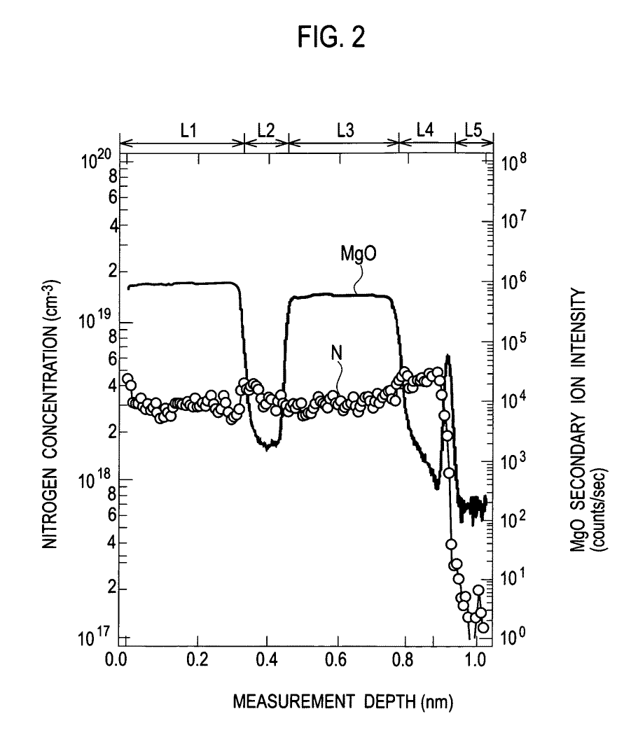

FIG. 2 shows the SIMS results for a laminate of alternately formed layers of MgZnO and ZnO thin films doped with nitrogen, the laminate being formed on top of an undoped ZnO substrate. In FIG. 2, an area L5 corresponds to the undoped ZnO substrate, areas L2 and L4 correspond to nitrogen-doped ZnO thin films, an area L1 corresponds to nitrogen-doped Mg_{0.23}ZnO, and an area L3 corresponds to Mg_{0.15}ZnO.

A comparison between the area L1 and the area L3 shows a fact that the amount of doped nitrogen differs little irrespective of the different Mg compositions. In addition, a comparison between the areas L2, L4 and the areas L1, L3 shows a fact that whether Mg is contained in the layer or not has little influence on the amount of doped nitrogen. The foregoing observations show the fact that, in a case of an MgₓZn₁₋ₓO film (0≦x≦0.5) thin film, the acceptor concentration must be 5×10²⁰ cm⁻³ or less in order to maintain the crystallinity of the base material.

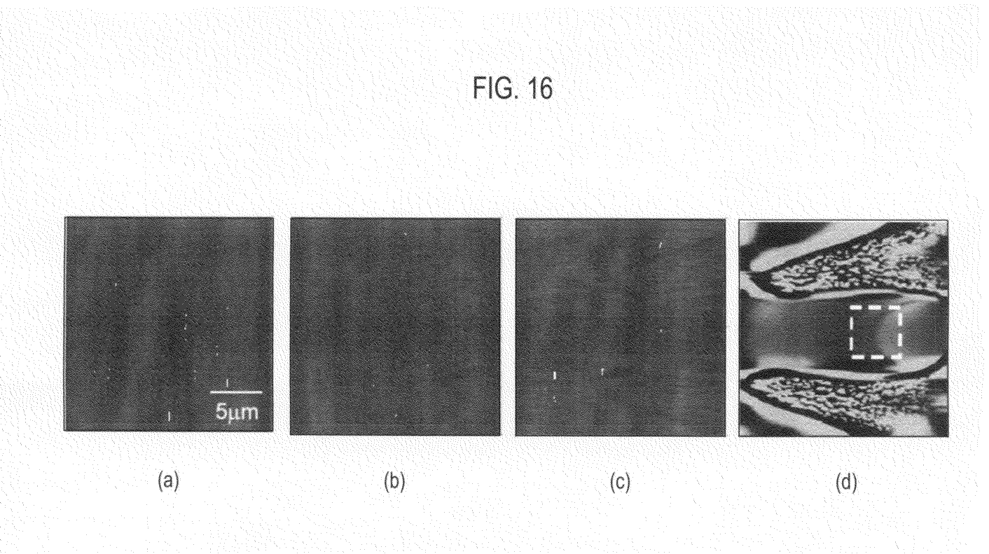

FIGS. 16, 4, and 5 together show the fact that there is a maximum allowed proportion of Mg composition in the MgₓZnO thin film. Firstly, nitrogen-doped MgₓZn₁₋ₓO films are grown respectively on ZnO substrates with different proportions of Mg composition (i.e., X values) from one another. The surfaces of these nitrogen-doped MgₓZn₁₋ₓO films are scanned using an atomic force microscope (AFM). Each of the images shown in FIG. 16 is in a field of view of 20 μm×20 μm. FIG. 16 (a) is the image of the surface of a nitrogen-doped MgₓZn₁₋ₓO film with a Mg-composition proportion X of 0.06. FIG. 16 (b) is the image of the surface of a film with a Mg-composition proportion X of 0.11. FIG. 16 (c) is the image of the surface of a film with a Mg-composition proportion X of 0.21. FIG. 16 (d) is the image of the surface of a film with a Mg-composition proportion X of 0.39. The surfaces of the MgₓZn₁₋ₓO films shown respectively in FIGS. 16 (a) to (c) are not rough, but a markedly uneven surface is shown in FIG. 16 (d). MgₓZn₁₋ₓO films with rough surfaces cause various problems in device fabrication. For this reason, no such films can be used for device fabrication. Accordingly, it can be found, from the viewpoint of the surface roughness, that the Mg-composition proportion X of the MgₓZn₁₋ₓO film needs to be lower than 0.39.

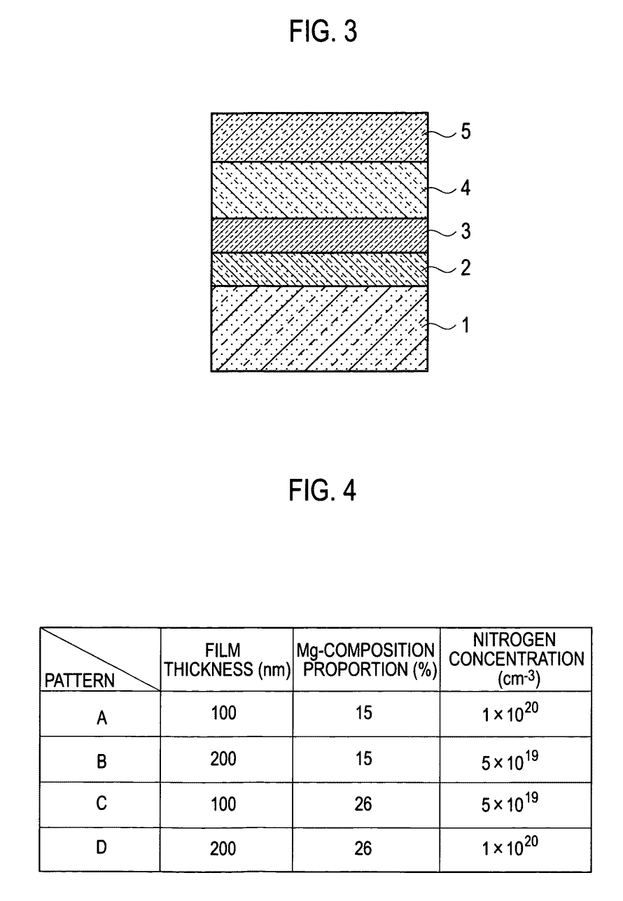

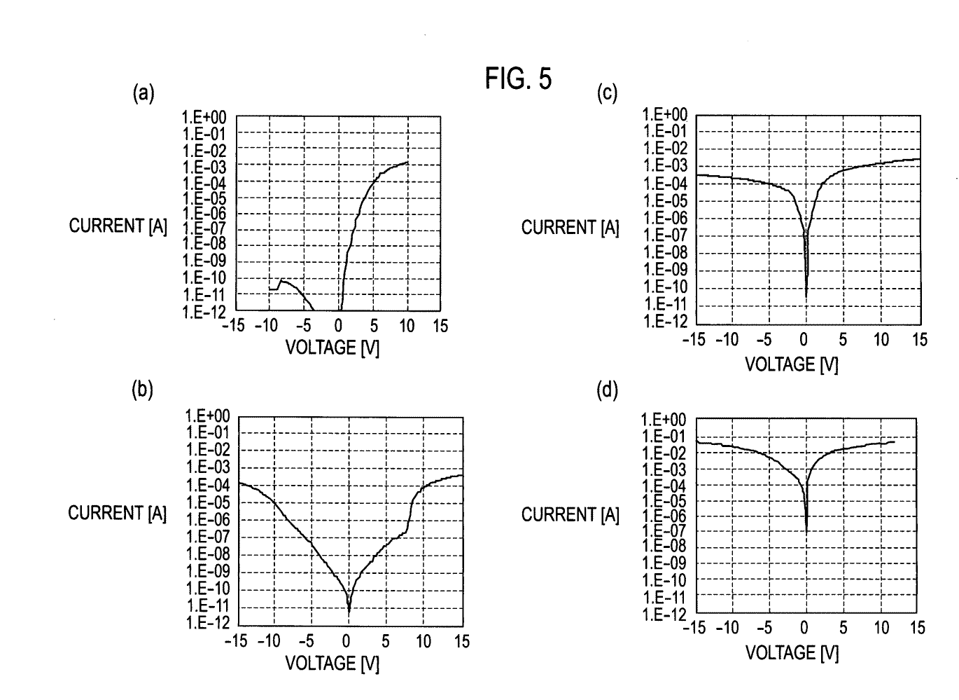

Next, FIGS. 4 and 5 indicate that there is a maximum proportion of Mg composition in the MgₓZnO thin film, from other view points than the surface roughness. FIGS. 4 and 5 show the results of examination obtained by fabricating semiconductor elements each made of the laminate shown in FIG. 3. On top of a ZnO substrate 1, a ZnO layer 2 of a 10-nm film thickness is grown; then, on top of the ZnO layer 2, a Mg_{0.1}ZnO layer 3 of a 100-nm film thickness is grown; and then, on top of the Mg_{0.1}ZnO layer 3, a MQW layer 4 of a 72-nm film thickness is grown. Then, the growth process is stopped for a moment while a radical source, which is a source of nitrogen, is warmed up for a minute or two. After that, a nitrogen-doped MgₓZn₁₋ₓO layer 5 is grown. The characteristics of the fabricated semiconductor elements are investigated by varying the film thickness of the uppermost nitrogen-doped MgₓZn₁₋ₓO layer 5, the proportion of Mg composition (the value of X) of the layer 5, and the amount of doped nitrogen for the layer 5. The MQW (MQW being the abbreviation of “multi-quantum well”) layer 4 is a multi-layer film in which Mg_{0.1}ZnO layers each having a 6-nm film thickness and ZnO layers each having a 2-nm film thickness alternately formed by 6 cycles.

The MgₓZn₁₋ₓO layers 5 of the semiconductor elements are formed in accordance with the combination patterns shown in FIG. 4. The Mg-composition proportion for both of the patterns A and B is 15%, whereas these two patterns differed from each other in the film thickness and the nitrogen concentration. Likewise, the Mg-composition proportion for both of the patterns C and D is 26%, whereas these two patterns differed from each other in the film thickness and the nitrogen concentration.

A voltage is applied to each of the semiconductor elements shown in FIG. 3 and fabricated in accordance with the patterns shown in FIG. 4 to investigate the current-voltage characteristics. FIG. 5 shows the results. FIG. 5 (a) corresponds to the pattern A of FIG. 4; FIG. 5 (b) corresponds to the pattern B of FIG. 4; FIG. 5 (c) corresponds to the pattern C of FIG. 4; and FIG. 5 (d) corresponds to the pattern D of FIG. 4. FIGS. 5(a) and (b) show that the semiconductor elements with 15% Mg-composition proportion in MgZnO exhibit the characteristics of diodes.

In contrast, FIGS. 5 (c) and (d) show that the semiconductor elements with 26% Mg-composition proportion in MgZnO do not exhibit the characteristics of diodes. The data of FIGS. 4 and 5 prove the fact that there is a maximum proportion of Mg composition if a device is made of MgZnO. Progress in doping technique and the temperature modulation method described in Non-Patent Document 2 may make it possible to fabricate a device made of MgZnO with a Mg-composition proportion of 26% or higher. At least, if a device is fabricated in accordance with the simpler, current doping technique, however, the proportion of Mg composition is preferably lower than 26%.

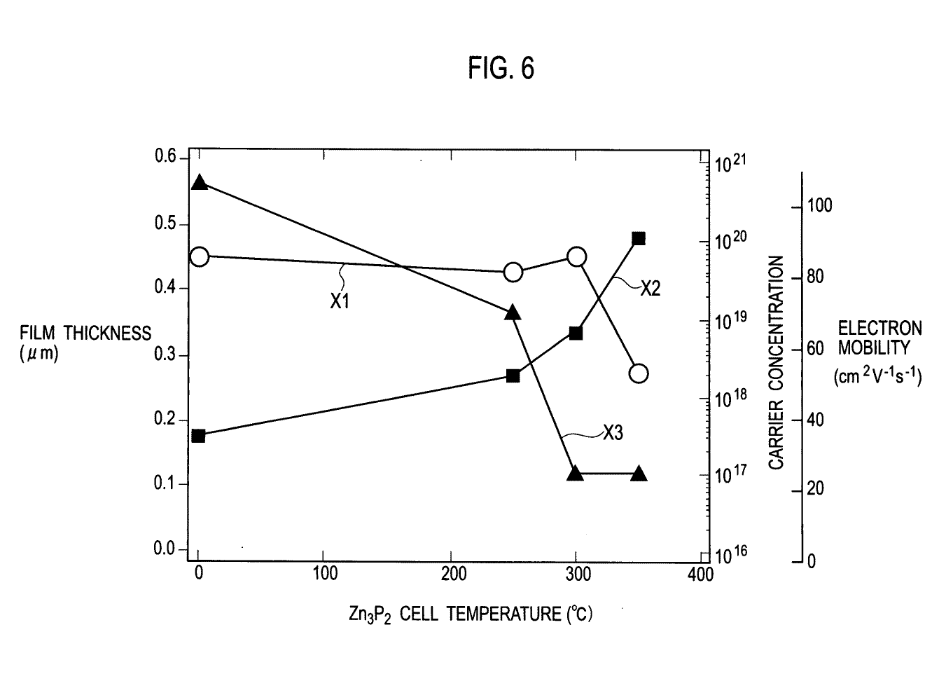

Subsequently, description will be given as to the acceptor for the ZnO thin film. Besides nitrogen, group VB elements to which nitrogen (N) belongs may be some possible materials that can be used as the acceptor. An investigation is conducted to find out the appropriate ones of those group VB elements for the use as p-type impurities. Phosphorus (P), which is a group VB element, is used, in place of nitrogen, as p-type impurities for the ZnO thin film in order to fabricate a phosphorus-doped ZnO. FIG. 6 shows the electric characteristics of the phosphorus-doped ZnO. The horizontal axis of FIG. 6 represents the temperature (° C.) of Zn₃P₂ cell. The graph X1 (white circle) represents the film thickness of the phosphorus-doped ZnO; the graph X2 (black square) represents the carrier concentration (cm⁻³); and the graph X3 (black triangle) represents the electron mobility. The results in FIG. 6 show that as the carrier concentration is increased, the electron mobility in the phosphorus-doped ZnO thin film is decreased.

When the doped phosphorus is investigated by SIMS, the results of the investigation show that all the phosphorus is of n-type, and do not function as the acceptor. Then, doping is conducted not using the simple substance of P (phosphorus) but using various compounds of P such as Zn₃P₂, P₂O₅, and GaP. The results thus obtained, however, are the same as ones obtained using the simple substance of P. This leads to a conclusion that nitrogen is the most appropriate material to be used as the p-type dopant.

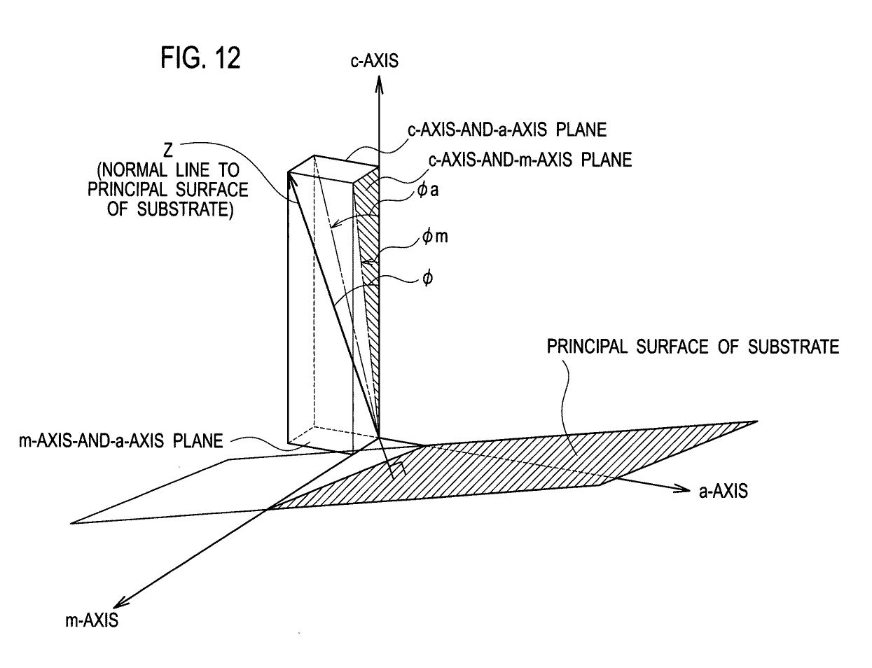

Subsequently, the effects, obtained by inclining c-axis on the principal surface of the MgₓZn₁₋ₓO film in the m-axis direction, will be described by referring to JP-2006-160273 of the same inventors. As shown in FIG. 12, an MgₓZn₁₋ₓO substrate 11 has been polished so that the normal line to the principal surface of the substrate having a +C plane can be inclined with respect to c-axis and the principal surface of the substrate can have a normal line thereto inclined at least from c-axis towards m-axis. In the case shown in FIG. 12: an angle Φ represents the inclination angle of a normal line Z to the principal surface of the substrate inclines from c-axis of the crystal axes of the substrate; an angle Φₘ represents the inclination angle, towards m-axis, of a shoot (projection) axis obtained by shooting (projecting) the normal line Z onto the c-axis-and-m-axis plane in the orthogonal coordinate system including the substrate crystal axes of c-axis, m-axis, and a-axis; an angle Φₐ represents the inclination angle, towards a-axis, of the shoot axis obtained by shooting the normal line Z onto the c-axis-and-a-axis plane.

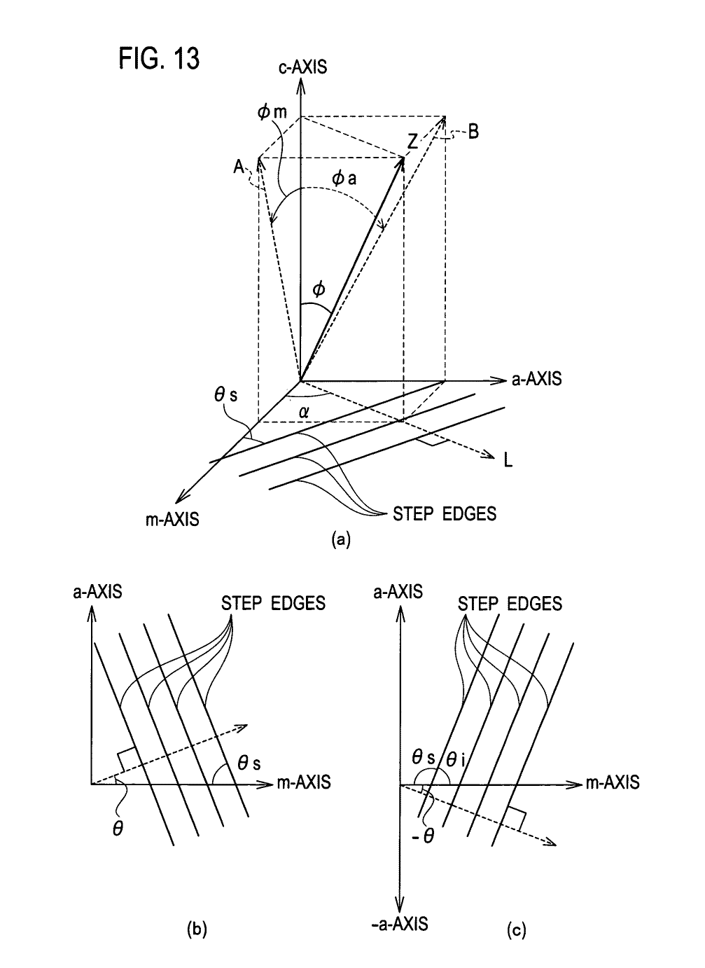

FIG. 12 shows a state of inclining normal line Z to the principal surface of the substrate, but FIG. 13 (a) shows the same state in a more understandable manner by focusing on the relationship between the normal line Z and the orthogonal coordinate system of c-axis, m-axis, and a-axis. The normal line Z to the principal surface of the substrate shown in FIG. 13 (a) and the normal line Z shown in FIG. 12 differ from each other in their respective inclining directions. What each of the symbols Φ, Φₘ, and Φₐ, means is the same between FIG. 13 (a) and FIG. 12. In FIG. 13 (a), a shoot axis A is obtained by shooting the normal line Z to the principal surface of the substrate onto the c-axis-and-m-axis plane in the orthogonal coordinate system of c-axis, m-axis, and a-axis, whereas a shoot axis B is obtained by shooting the normal line Z onto the c-axis-and-a-axis plane.

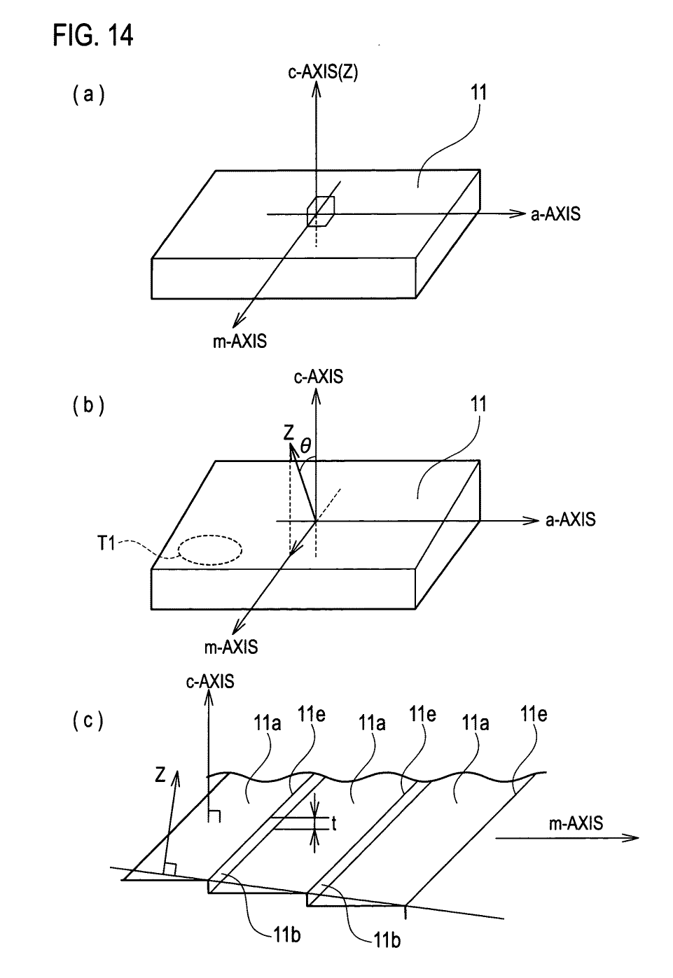

Now, description will be given of the reason why the normal line to the principal surface of the substrate inclines from c-axis towards m-axis. A schematic diagram is shown in FIG. 14 (a). In this diagram, the normal line Z to the principal surface of the substrate having +C plane does not incline towards any of a-axis and m-axis, so that the normal line Z coincides with the +c-axis. The direction in which the normal line Z extends, that is, the vertical direction of the principal surface of the substrate 11 coincides with the +c-axis direction. Each of a-axis, m-axis, and c-axis intersects orthogonally to the others.

In a bulk crystal, the direction of the normal line to the principal surface of the wafer does not coincide with the c-axis direction as shown in FIG. 14 (a) unless a cleavage plane of the crystal is used. The use of only the just-angle C-plane substrates results in poor productivity. Actually, the normal line Z to the principal surface of the wafer inclines from c-axis, and has an off-angle. Take a case shown in FIG. 14 (b) as an example. In this case, the normal line Z to the principal surface exists within the c-axis-and-m-axis plane and inclines from c-axis towards m-axis by 8 degrees. FIG. 14 (c) is an enlarged diagram of a portion of the surface of substrate 11 (e.g., an area T1). As FIG. 14 (c) shows, the surface has terrace faces 11a, which are flat faces, and step faces 11b, which are regularly arranged equidistantly at step portions formed by the inclination of the normal line Z.

Note that the terrace faces 11a correspond to C planes (0001), whereas the step faces 11b correspond to M-planes (10-10). As FIG. 14 (c) shows, the step faces 11b thus formed are arranged regularly while allowing each of the terrace faces 11a to have a certain width in the m-axis direction. Consequently, c-axis, which is perpendicular to the terrace faces 11a and the normal line Z to the principal surface of the substrate together form an off-angle of θ degrees.

The state shown in FIG. 14 (c) corresponds to a case where the angle θ_{S} in FIG. 13 is 90 degrees. Note that the step edges shown in FIG. 13 are obtained by projecting the step portions formed by the step faces 11b onto the a-axis-and-m-axis plane. As described above, if the step faces are made to be a plane corresponding to M plane, a flat film can be formed as a ZnO-based semiconductor layer formed by making a crystal grow on the principal surface. Step portions are formed in the principal surface by the step faces 11b, but the atoms flown to the step portions can be trapped in a more stable manner than the atoms flown to the terrace faces 11a. This is because, each of the atoms flown to the step faces 11b is bonded to both of the two faces (i.e., one of the terrace faces 11a and one of the step faces 11b).

In a surface diffusion process, flying atoms diffuse within terraces, but are trapped in the step portions where the bonding force is stronger and at kink positions formed by the step portions. The atoms thus trapped are incorporated into the crystal. This way of crystal growth is known as the lateral growth, which guarantees a stable growth of the crystal. In this way, if a ZnO-based semiconductor layer is formed on top of a substrate with the normal line to the principal surface thereof inclining at least m-axis direction, the crystal of the ZnO-based semiconductor layer grows around the step faces 11b. Thus formed is a flat film. Once a flat MgₓZn₁₋ₓO film has been fabricated on top of the substrate 11 in this way, c-axis of the substrate 11 and c-axis of the MgₓZn₁₋ₓO film are parallel with each other. Accordingly, if the normal line Z to the principal surface of the substrate 11 inclines by an angle of Φ from c-axis of the substrate 11, the normal line Z inclines by an angle of Φ from c-axis of the crystal axes of the MgₓZn₁₋ₓO film formed on the substrate 11.

As has been described thus far, it is preferable that the normal line Z to the principal surface should exist within the c-axis-and-m-axis plane and that the normal line Z should incline from c-axis only towards m-axis. In practice, however, it is difficult to cut the wafer with the inclination only towards m-axis. So, it is necessary to allow the normal line Z to incline towards a-axis and to set the allowable degree for the inclination. For example, as FIG. 13 shows, it is allowable to form the principal surface so that: an angle Φ can be formed by the inclination of the normal line Z to the principal surface of the substrate from c-axis of the axes of the crystal for the substrate; an angle Φₘ can be formed by the inclination, towards m-axis, of the shoot axis obtained by shooting the normal line Z onto the c-axis-and-m-axis plane in the orthogonal coordinate system of c-axis, m-axis, and a-axis, which are the axes of the crystal for the substrate; and an angle Φₐ can be formed by the inclination, towards a-axis, of the shoot axis obtained by shooting the normal line Z onto the c-axis-and-a-axis plane. In this case, however, it is necessary to keep the angle θ_{S} made by each of the step edges with the m-axis direction within a certain range. The inventors have found out this necessity by an experiment.

In addition, for the purpose of fabricating a flat film, it is necessary to arrange the step edges regularly in the m-axis direction. If the step edges are arranged at irregular intervals or the lines of the step edges are not in proper order, the above-mentioned lateral growth cannot be possible. Consequently, no flat film can be fabricated.

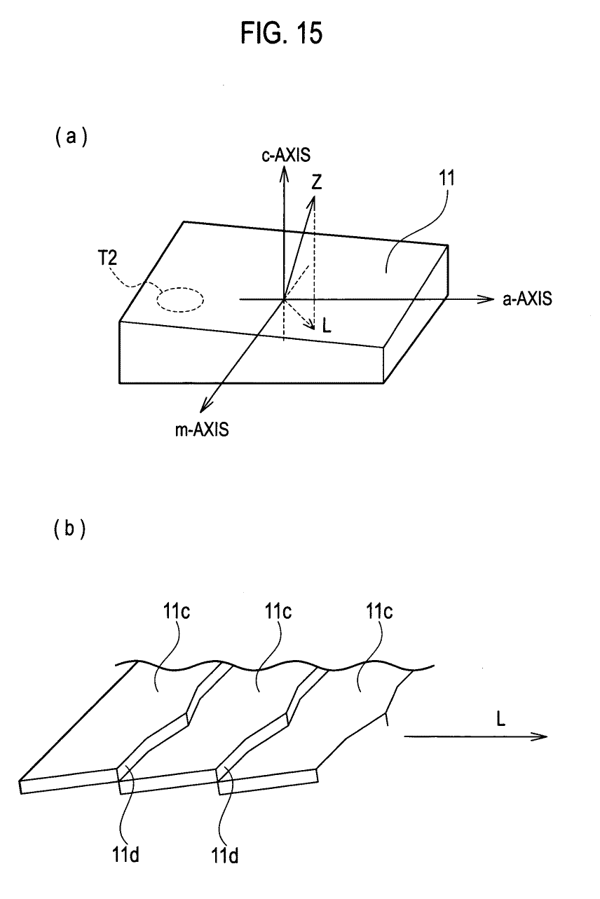

FIG. 13 shows a principal surface of a substrate with its normal line Z inclining both towards m-axis and towards a-axis, and such principal surface is shown in FIG. 15 (a). The coordinate axes are set in the same manner as those in FIG. 14. In FIG. 15 (a), a direction denoted by L is the direction of the projection axis obtained by projecting the normal line Z to the principal surface of the substrate onto the a-axis-and-m-axis plane of the orthogonal coordinate system of c-axis, m-axis, and a-axis, which are the axes of the crystal for the substrate. FIG. 15 (b) is an enlarged diagram illustrating a portion of the surface of the substrate 11 (e.g., an area T2). In the surface, there are terrace faces 11c, which are flat faces, and step faces 11d, which are formed at the step portions formed by the inclination. The terrace faces are C-planes (0001) in the case of FIG. 15 (a). The case of FIG. 15 (a) differs from the case of FIG. 14 in that the normal line Z inclines by an angle Φ from c-axis that is perpendicular to the terrace faces.

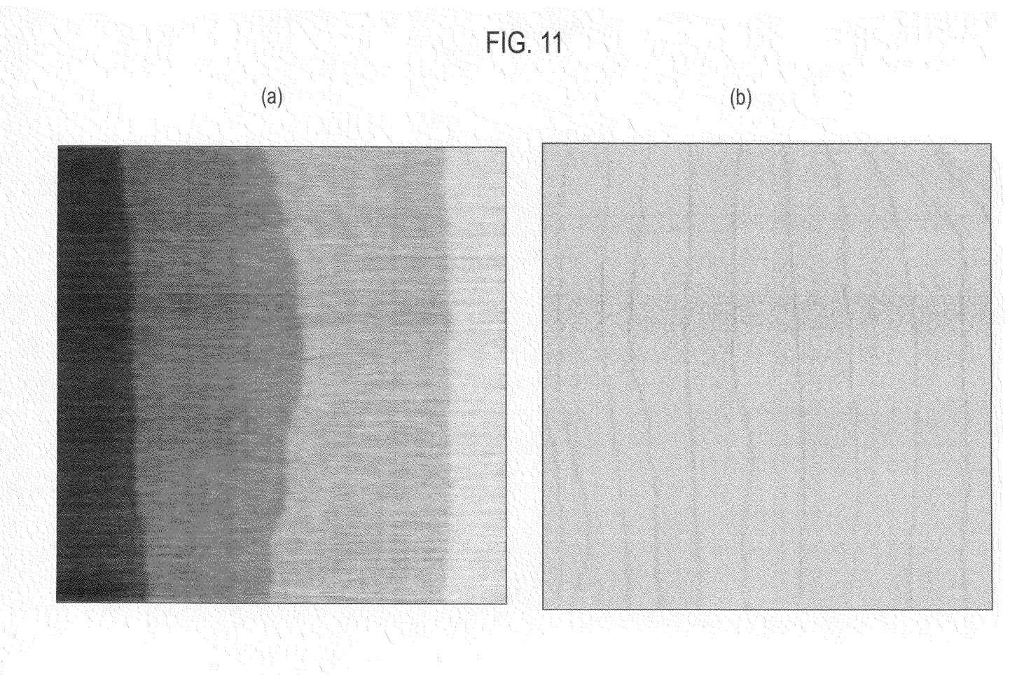

The direction of the normal line to the principal surface of the substrate inclines not only towards m-axis but also towards a-axis. Accordingly, the step faces are formed obliquely, so that the step faces are arranged in the L-direction. In this state, the step edge arrangement extends in the L-direction as in the case shown in FIG. 13. Since M-plane is a thermally and chemically stable plane, the inclination angle Φa, in the a-axis direction, of a certain range may result in a failure of keeping the oblique steps neatly, may result in the formation of uneven surfaces of the step faces, and may result in the arrangement of the step edges that is not in proper order. The end result is the impossibility of forming a flat film on top of the principal surface. FIG. 11 (b) shows this state.

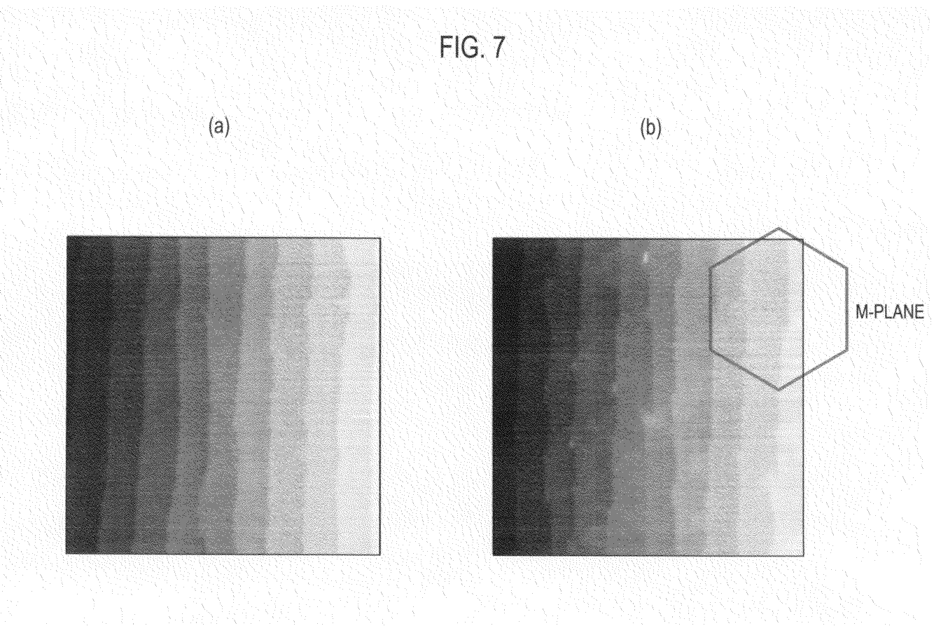

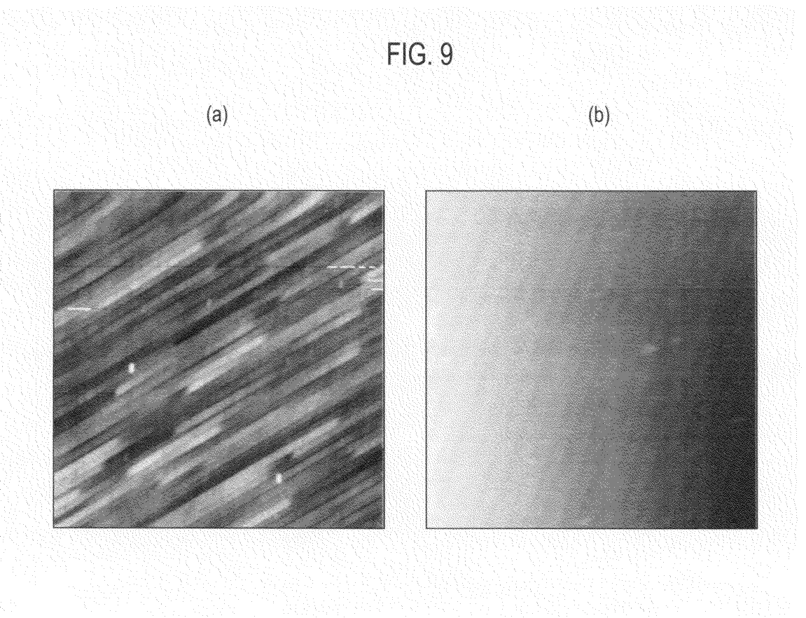

Subsequently, description will be given as to the fact that M-plane of the MgZnO thin film or substrate is thermally and chemically stable. Using an AFM, the surface of an MgₓZn₁₋ₓO substrate is scanned. Each of the images shown in FIG. 9 is obtained by a scan on a field of view of 5 μm×5 μm. Each of the images shown in FIGS. 7, 8, and 10 is obtained by a scan on a field of view of 1 μm×1 μm.

Exposed A-plane of the MgₓZn₁₋ₓO substrate is subjected to an annealing process in an atmosphere at a temperature of 1100° C. for two hours. FIG. 9 (a) shows the state of the resultant A-plane. Exposed M-plane of the MgₓZn₁₋ₓO substrate is subjected to an annealing process in an atmosphere at a temperature of 1100° C. for two hours. FIG. 9 (a) shows the state of the resultant M-plane. The surface shown in FIG. 9 (b) is neat, whereas the surface shown in FIG. 9 (a) is in an unfavorable state. This is because step bunching appears in the surface of FIG. 9 (a), and the width of the steps and the step edges are not in proper order. These facts show that M-plane is a thermally stable plane.

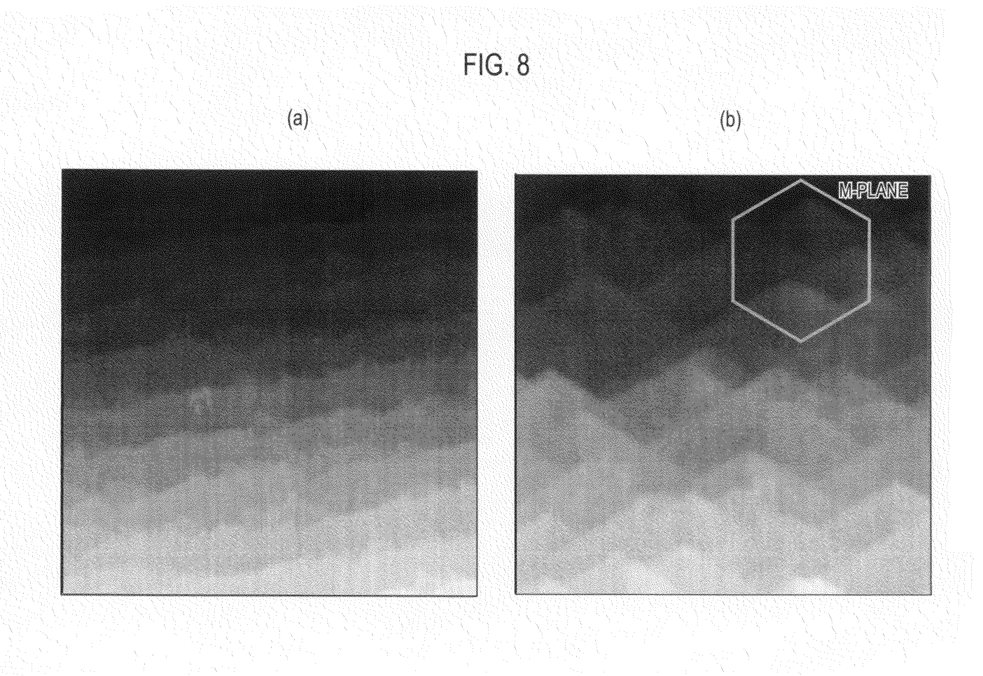

On one hand, FIG. 8 (a) shows a surface state of a case, such as one shown in FIG. 15 (b), in which the direction of the normal line to the principal surface of an MgₓZn₁₋ₓO substrate inclines by an angle of D degrees from c-axis so that M-plane cannot appear neat. The surface is subjected to an etching process with hydrochloric acid of 5% for 30 seconds. FIG. 8 (b) shows the state of the resultant surface. A hexagonal area shown in FIG. 8 (b) shows the fact that the planes other than M-plane are removed by the etching with hydrochloric acid and thus M-plane appears particularly noticeable.

On the other hand, FIG. 7 (a) shows a surface state of a case, such as one shown in FIG. 14 (c), in which the direction of the normal line to the principal surface of an MgₓZn₁₋ₓO substrate inclines from c-axis only towards m-axis. FIG. 7 (a) shows that the step edges of M-plane are arranged perpendicularly to m-axis. The surface is subjected to an etching process with hydrochloric acid of 5% for 30 seconds. FIG. 7 (b) shows the state of the resultant surface. As shown in FIG. 7 (b), no noticeable change in the surface state can be observed even after etching. The data of FIGS. 7 to 9 proves the fact that M-plane is a chemically stable plane.

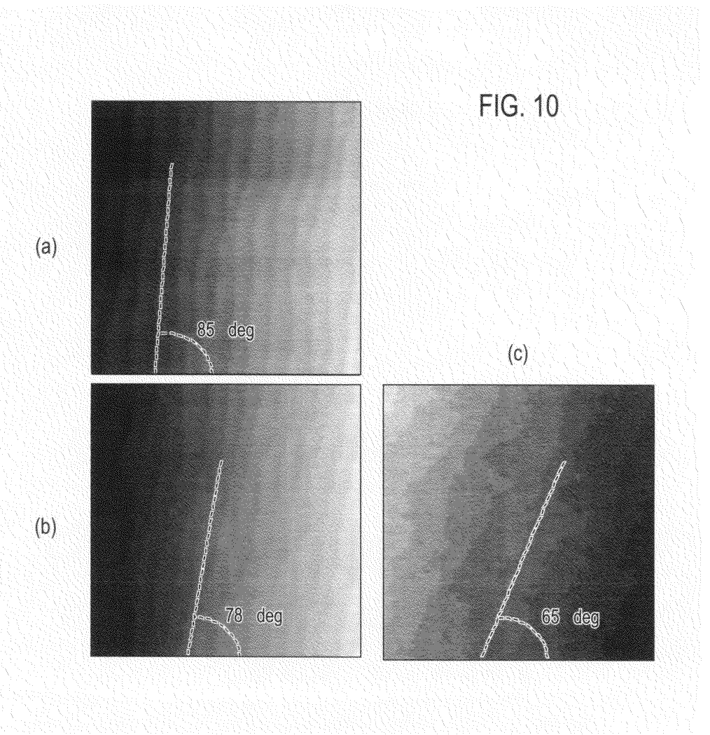

FIG. 10 shows how the step edges and step width change if the normal line to the principal surface having C-plane in growth plane has not only an off-angle in the m-axis direction but also an off-angle in the a-axis direction. To conduct a comparison, the off-angle Φₘ in the m-axis direction described by referring to FIG. 13 is fixed at 0.4 degrees, and the off-angle Φₐ in the a-axis direction is changed to become larger. This is accomplished by changing the cutting-out face of the MgₓZn₁₋ₓO substrate. If the cutting-out face of the MgₓZn₁₋ₓO substrate is changed, an accurate cutting can be accomplished by designating the position of the crystal boule in terms of orientations by use of an X-ray diffraction (XRD) apparatus.

With a change to make the off-angle Φₐ in the a-axis direction larger, the angle θ_{S} made by each step edge with the m-axis direction is changed to become larger. For this reason, each image of FIG. 10 is shown with the magnitude of the angle θ_{S}. FIG. 10 (a) shows an image of a case where the angle θ_{S}=85 degrees. Both the step edges and the step width are in proper order. FIG. 10 (b) shows an image of a case where the angle θ_{S}=78 degrees. A slight disorder is observable, but both the step edges and the step width are observable. FIG. 10 (b) shows an image of a case where the angle θ_{S}=65 degrees. The disorder is worsened, and neither the step edges nor the step width can be observed. If a ZnO-based semiconductor layer is grown epitaxially on top of a surface in the state shown in FIG. 10 (c), no flat film can be formed. If the angle θ_{S} of FIG. 10 (c) is converted to the corresponding inclination Φₐ in the a-axis direction, the magnitude of the inclination Φₐ is 0.15 degrees. The data described thus far show the fact that the angle θ_{S} is preferably within a range 70 degrees≦θ_{S}≦90 degrees.

Description will be given as to a method of forming the ZnO-based thin film. Firstly, a ZnO-based substrate is placed in a load-lock chamber, and heated for 30 minutes in a vacuum environment of approximately 1×10⁻⁵ to 1×10⁻⁶ Torr in order to remove the moisture. The substrate passes through a conveying chamber with a vacuum of approximately 1×10^{˜}9 Torr, and then is introduced to a growth chamber having a wall surface cooled with liquid nitrogen. Then, a ZnO-based thin film is grown by the MBE method.

To supply Zn, a Knudsen cell with high-purity Zn of 7N placed in a crucible made of PBN is used to heat the Zn up to a temperature range from approximately 260 to 280° C. Thus, the high-purity Zn is sublimed, and the sublimed Zn is supplied in the form of Zn molecular beams. Mg is an example of IIA-group elements. To supply Mg, high-purity Mg of 6N is used, and is heated, by use of a cell having a similar structure, up to a temperature range from approximately 300 to 400° C. Thus, the high-purity Mg is sublimed, and the sublimed Mg is supplied in the form of Mg molecular beams.

To supply oxygen, O₂ gas of 6N is used. The O₂ gas passes through an SUS tube having an electrolytically-polished internal surface, and is then supplied, at a rate ranging from approximately 0.1 sccm to 5 sccm, to a RF radical cell equipped with a discharge tube where a small orifice is formed in a part of a cylinder. Then, a RF high frequency of approximately 100 to 500 W is applied to the RF radical cell so that plasma can be produced from the O₂ gas. The O₂ gas is turned to be in the oxygen-radical state with a higher reactive activity, and the oxygen radical is supplied as the oxygen source. Producing plasma is important because no ZnO-based thin film can be formed by use of O₂ raw gas. To supply nitrogen, pure N₂ gas or gas of a nitrogen compound is used. The gas is supplied, at a rate ranging from approximately 0.1 sccm to 5 sccm, to a RF radical cell as in the case of oxygen. Then, a RF high frequency of approximately 50 W to 500 W is applied to the RF radical cell so that plasma can be produced from the gas. The gas is turned to be in the N-radical state with a higher reactive activity, and the N-radical is supplied as the nitrogen source.

To heat the substrate, a SiC-coated carbon heater is used as a commonly-used means for resistance heating. Metal-based heaters such as one made of W cannot be used because the metal is oxidized. Heating by lamp, by laser, or other method of heating can also be employed as long as the method relies on materials highly resistant against oxidation.

The temperature of the substrate is raised up to 750° C. or higher, and the substrate is heated for approximately 30 minutes in a vacuum of approximately 1×10^{˜}9 Torr. Then, the shutters of the oxygen radical cell and of Zn cell are opened so as to start the growth of the ZnO thin film. If an MgZnO thin film is grown, the shutter of the Mg cell is also opened. If nitrogen is doped, the shutter of nitrogen radical cell is also opened.

1. A ZnO-based thin film characterized by comprising a MgₓZn₁₋ₓO film (0≦X<0.5) being formed on top of a substrate, containing at least one kind of p-type dopant, and having an acceptor concentration that is 5×10²⁰ cm⁻³ or less.

2. The ZnO-based thin film according to claim 1 characterized in that the MgₓZn₁₋ₓO film has a Mg-composition X that is lower than 0.39.

3. The ZnO-based thin film according to claim 1 characterized in that the MgₓZn₁₋ₓO film has a Mg-composition X that is lower than 0.26.

4. The ZnO-based thin film according to claim 1 characterized in that the p-type dopant is an element selected from group VB elements.

5. The ZnO-based thin film according to claim 4 characterized in that the selected element is nitrogen.

6. The ZnO-based thin film according to claim 1 characterized in that the substrate is made of a ZnO-based material.

7. The ZnO-based thin film according to claim 1 characterized in that a normal line to a principal surface of the substrate inclines from c-axis of the crystal axes of the MgₓZn₁₋ₓO film.

8. The ZnO-based thin film according to claim 1 characterized in that the normal line to the principal surface of the substrate inclines from c-axis of the crystal axes of the substrate.

9. The ZnO-based thin film according to claim 8 characterized in that the direction in which the normal line to the principal surface of the substrate inclines is the m-axis direction.

10. The ZnO-based thin film according to claim 7 characterized in that the direction in which the normal line to the principal surface of the substrate inclines is the m-axis direction.
